(19) United States
(12) Patent Application Publication
(10) Pub. No.: US 2013/0140688 A1
(43) Pub. Date: Jun. 6, 2013

(54) Through Silicon Via and Method of Manufacturing the Same

(71) Applicants: Chun-Hung Chen, Tainan City (TW); Ming-Tse Lin, Hsinchu City (TW); Yung-Chang Lin, Taichung City (TW)

(72) Inventors: Chun-Hung Chen, Tainan City (TW); Ming-Tse Lin, Hsinchu City (TW); Yung-Chang Lin, Taichung City (TW)

(21) Appl. No.: 13/309,566

(22) Filed: Dec. 2, 2011

(51) Int. Cl. H01L 23/48; H01L 21/768

(52) U.S. Cl. 257/737; 438/613; 257/E21.577; 257/E23.021

(57) ABSTRACT

The present invention discloses a through silicon via and method of manufacturing the same comprising the steps of providing a substrate, forming a plurality of through silicon via (TSV) holes in said substrate, forming a seed layer on the surface of said substrate and said a plurality of TSV holes, forming a patterned mask on said substrate, wherein said patterned mask comprises a plurality of first openings corresponding to said TSV holes and a plurality of second openings adjacent to or surrounding said a plurality of first openings, forming a material layer on said substrate, wherein said material layer is filled into said TSV holes and said first openings to form a plurality of through silicon vias, and said material layer is filled into said second openings to form a plurality of dummy bumps.

### BACKGROUND OF THE INVENTION

1. Field of the Invention

The present invention relates generally to a through silicon via (TSV) and a method of manufacturing the same. In particular, the present invention relates to a through silicon via structure with higher filling uniformity and a method of manufacturing the same, which is aimed to overcome the issue of the conventional loading effect of prior art.

2. Description of the Prior Art

The response speed of IC circuits is related to the linking distance between devices disposed on a chip. For signal to be transmitted, the shorter the linking distance is, the faster the operational speed of a circuit device can be. Since the vertical distance between adjacent layers is much shorter than the width of a single-layer chip, IC circuits with a three-dimensional structure can shorten the linking distances of devices disposed on a chip. Accordingly, their operational speed can be increased when a chip is designed with a vertical packed structure in 3D IC schemes.

In order to integrate different devices in one single stacked structure chip, interconnects are required between die and die to electrically connect the devices on each level. The through silicon via (TSV) is one of the novel semiconductor technique developed for this purpose. Using TSV as interconnects in a vertical direction may overcome the limitations of wafer bonding, and further increase the transmission efficiency of signals. TSV technique produces devices that meet the market trends of “light, thin, short and small” through the 3D stacking technique and also provides wafer-level packages utilized in micro electronic mechanic system (MEMS), photo-electronics and electronic devices.

Nowadays, the TSV structure is usually obtained by performing the following steps: first, forming via hole on the front side of a wafer by etching or laser process. Secondly, filling said via hole with a conductive material, such as poly-Si, copper or tungsten, to form a conductive path (i.e. the interconnect structure). Finally, the back side of the wafer, or die, is thinned to expose the conductive path. After the manufacture of the TSV, the wafers or dies are be stacked together so that their conductive paths are connected to each other to provide electrical connection between wafers or dies. The 3D-stacked IC structure is accordingly obtained.

In the TSV process today, especially in the via last process, which forming step of the via hole is performed after the completion of a FEOL process and a BEOL process, or in the via middle process, which forming step of the via hole is performed right after the completion of a FEOL process, the plug in the TSV hole is usually formed of a material with excellent conductivity, such as copper or tungsten, by electro-chemical plating (ECP) process.

However, conventional ECP processes suffer from uniformity issues due to the loading effect. As shown in FIG. 1, which illustrates the cross-sectional view of a plurality of TSV structures 100 made by ECP process, it is clearly shown in the figure that the TSV hole 102a closer to the isolated region 104 will have lower hole-filling rate than the TSV hole 102 in dense region, therefore the TSV formed in the TSV hole 102a will have a significantly recessed profile. For this reason, the flatness of each TSV 100 is quite different. Uniform plating surface is difficult to achieve. This defect would result in the failure of devices.

Accordingly, an improved method of manufacturing TSV structures is necessary in the industry so that the TSV holes in isolated regions and dense regions are substantially the same, in order to improve the uniformity of the hole-filling process.

### SUMMARY OF THE INVENTION

To improve the filling uniformity of TSV, the present invention provides an improved TSV structure and a method of manufacturing the same. By forming dummy opening patterns surrounding the original TSV holes, all of the TSV holes may be situated in an deposition environment with a substantially the same pattern density. This way, all of the TSV holes can be provided with a substantially identical electroplating rate to avoid the loading effect.

One object of the present invention is to provide a TSV structure, which comprises a substrate, a plurality of TSV embedded in said substrate and protruded from the surface of said substrate, and a plurality of dummy bumps disposed on said substrate and adjacent to said plurality of TSV.

Another object of the present invention is to provide a method of manufacturing TSV electrodes, which comprises the steps of providing a substrate, forming a plurality of TSV holes in said substrate, forming a seed layer on the surface of said substrate and said plurality of TSV holes, forming a patterned mask on said substrate, wherein said patterned mask comprise a plurality of first openings corresponding to said plurality of TSV holes respectively, and a plurality of second openings adjacent to said plurality of first openings, and forming a material layer on said substrate, wherein said material layer is filled into said plurality of TSV holes and said plurality of first openings to form a plurality of TSV, and said material layer is filled into said plurality of second openings to form a plurality of dummy bumps.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a better understanding of the embodiments, are incorporated in, and constitute a part of this specification. The drawings illustrate some of the embodiments and, associated with the description, serve to explain the principles of the present invention.

FIG. 1 is a schematic cross-sectional view illustrating a plurality of TSV formed by electro-chemical plating process.

FIGS. 2, 3A, 4, 5A, 6, 7A, 8 and 9 are schematic cross-sectional views illustrating the process flow of manufacturing the TSV structure in accordance with embodiments of the present invention.

FIGS. 3B, 5B and 7B are top views illustrating parts of the process flow of manufacturing the TSV structure in accordance with embodiments of the present invention.

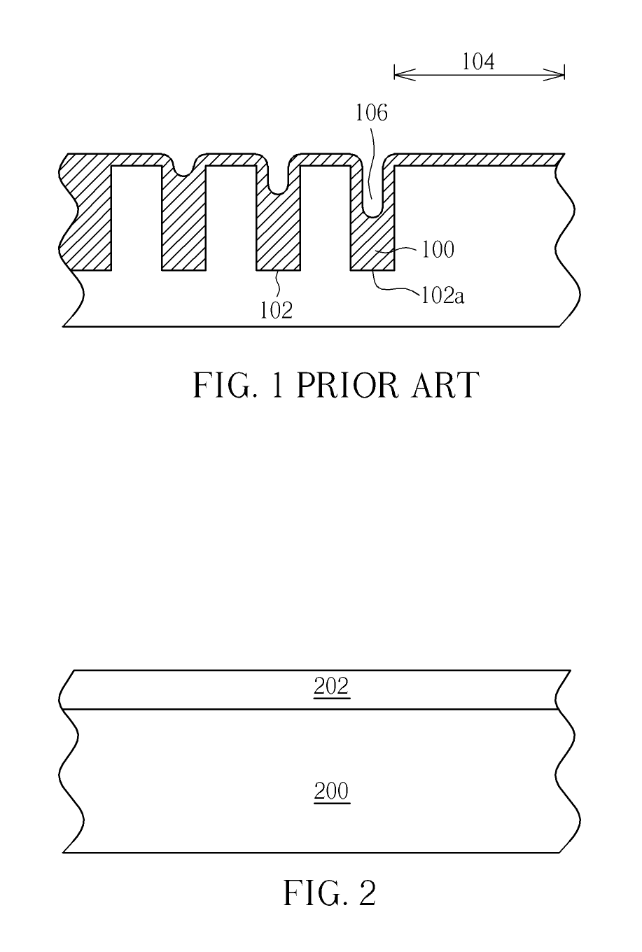

It should be noted that all the figures are diagrammatic. Relative dimensions and proportions of parts of the drawings may not be up to scale, for the sake of clarity and convenience in the drawings. The same reference signs are generally used to refer to corresponding or similar features in modified and different embodiments.

### DETAILED DESCRIPTION

Please refer to FIGS. 2-8. FIGS. 2-8 show sequential cross-sectional views of the process flow in accordance to the present invention. First, as shown in FIG. 2, a substrate 200 is provided. The material of the substrate 200 may be monocrystalline silicon, gallium arsenide (GaAs) or other well-known semiconductor material. In one embodiment of present invention, in via middle process for example, a FEOL process may be performed first on the surface of the substrate 200. For example, a standard metal-oxide semiconductor (MOS) transistor fabrication process is performed to form at least one MOS transistor (not shown), or another semiconductor device, on the semiconductor substrate 200. The MOS transistor could be a PMOS transistor, a NMOS transistor, or a CMOS transistor and the MOS transistor could also include typical transistor structures, including gates, spacers, lightly doped drains, source/drain regions and/or salicides. The detailed description is omitted herein.

After completing the aforementioned FEOL process, a dielectric layer 202 may be blanket-deposited on the surface of the substrate 200 by chemical vapor deposition (CVD). The dielectric layer 202 is preferably a composite layer constituted of tetraethylorthosilicate (TEOS) and phosphosilicate glass (PSG), but not limited thereto. The dielectric layer 202 may also be constituted of BPSG or low-k dielectric material, and a stress material layer, such as a tensile or compressive stress layer composed of silicon nitride, an etch stop layer composed of silicon nitride, a thin oxide cap layer, or combination thereof, may be optionally formed between the dielectric layer 202 and the MOS transistor.

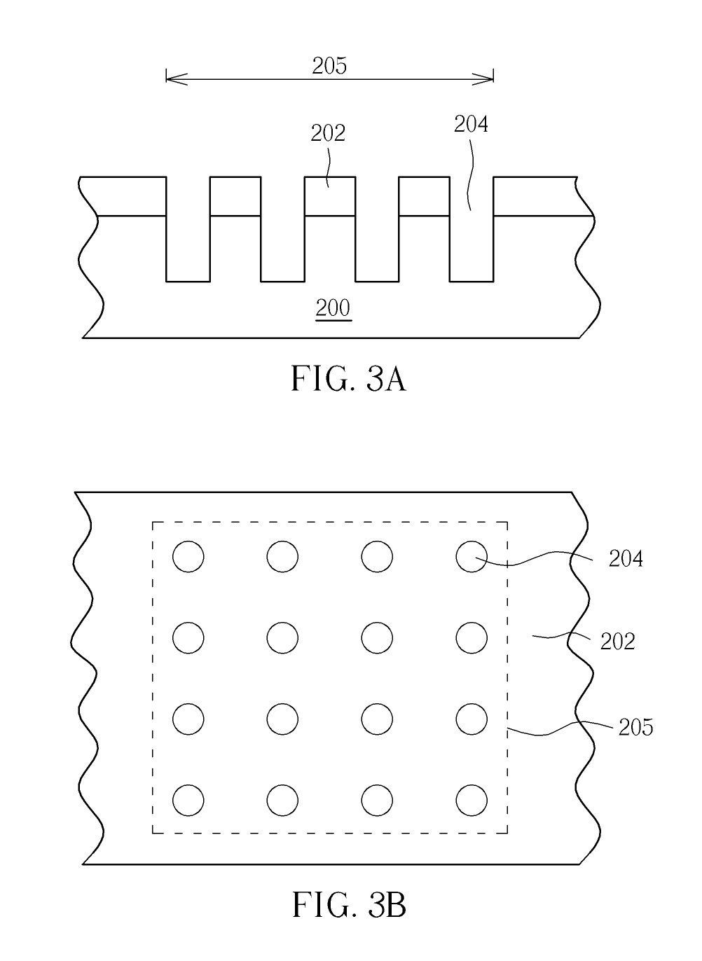

After forming the dielectric layer 202, as shown in FIG. 3A, a plurality of through silicon via (TSV) holes 204 having a predetermined aspect ratio are formed in the dielectric layer 202 and substrate 200. The TSV holes 204 may be formed by the method of forming a patterned hard mask (e.g. silicon nitride layer) first, and then performing a single or multiple etching processes to obtain the hole structure. In a preferred embodiment of the present invention, as shown in FIG. 3B, the TSV holes 204 are formed in a TSV region 205 on dielectric layer 202 and may be arranged in array. Please note that dielectric layer 202 may not be provided in some embodiment of present invention. In this case, the TSV holes 204 are only formed in the substrate 200.

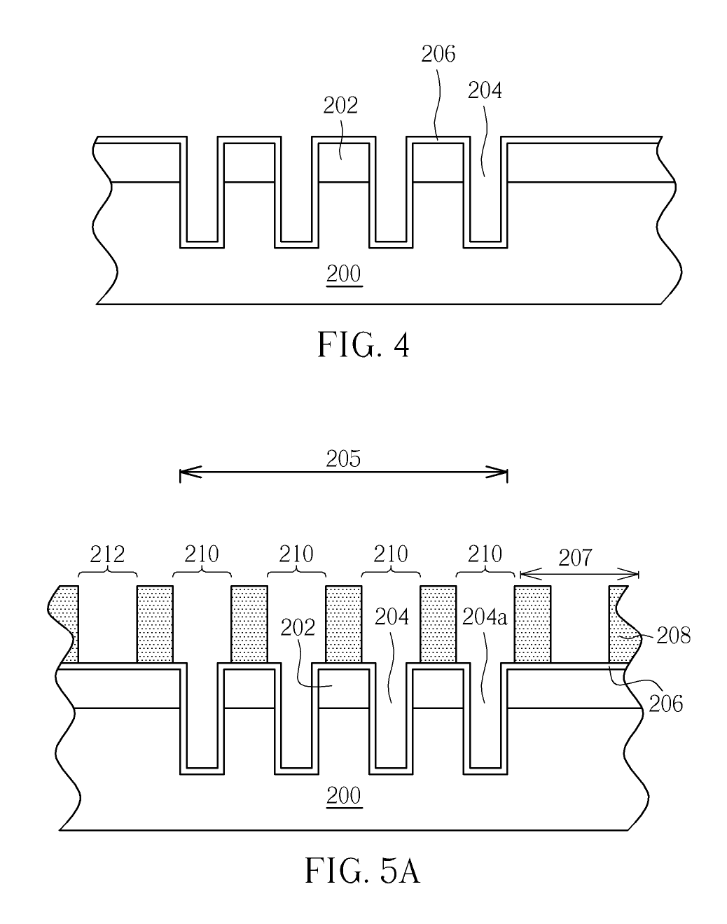

Subsequently, as shown in FIG. 4, a seed layer 206 is formed on the surface of the dielectric layer 202 and on the sidewalls of the TSV holes 204. The seed layer 206 may be formed by sputter process, with materials such as copper (Cu) or tungsten (W). The seed layer 206 may facilitate the formation of a subsequent electroplating process to form plug structures in the TSV holes 204. In a further embodiment, a liner layer or a barrier layer (not shown) is optionally formed between the dielectric layer 202 and the seed layer 206. The liner layer may act as a buffer layer for the seed layer 206 to adhere firmly on the surface of the dielectric layer 202, and electrically insulate the dielectric layer 202 from the seed layer 206. The liner layer may comprise insulating materials such as oxides or nitrides, and may be a single or a composite layer. The barrier layer material is preferably selected from a group consisting of Ta, TaN, Ti, and TiN, which could be used to prevent copper ions of the metal layer from migrating to the surrounding liner layer or to the substrate 200.

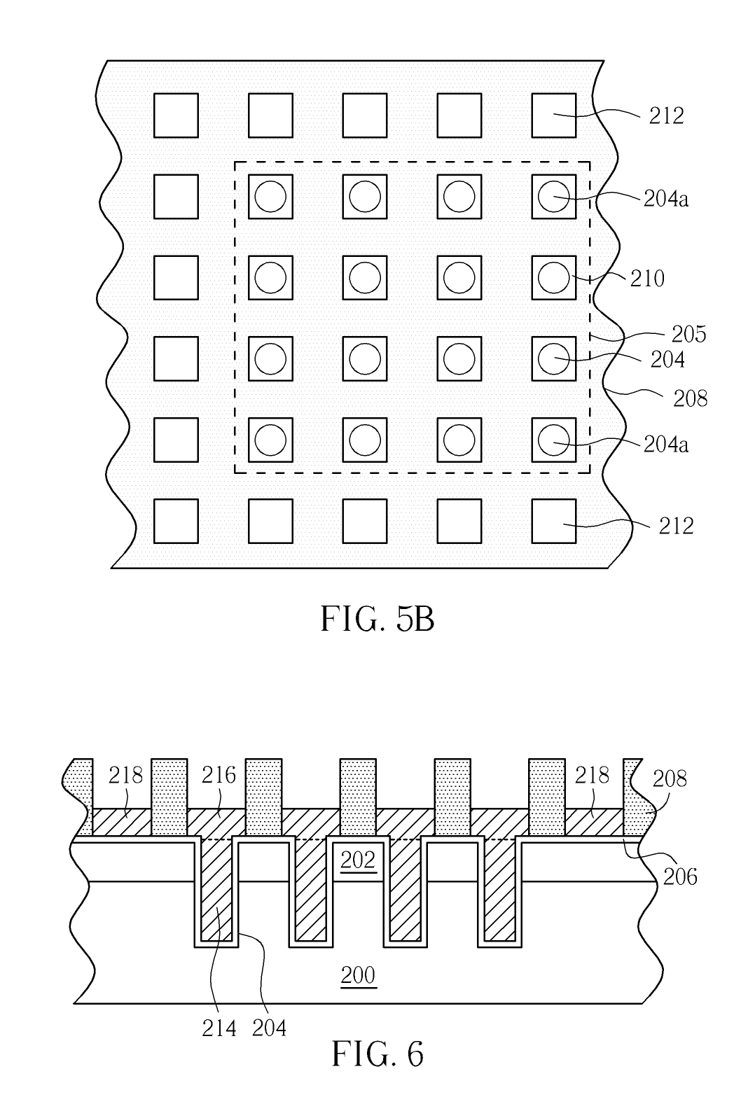

In the following step, as shown in FIG. 5A, a mask 208 (e.g. a photo resist) with a specific pattern is formed on the seed layer 206 at the surface of the dielectric layer 202. The mask 208 is used in the subsequent electroplating process to form a specific opening pattern. In a preferred embodiment of the present invention, the pattern of the mask 208 is a plurality of opening patterns including at least one first opening patterns 210 and at least one second opening patterns 212. As shown in FIG. 5B, each first opening pattern 210 is corresponding to a TSV hole 204, wherein the width of the first opening pattern 210 may be larger than the diameter of the TSV hole 204. The second opening patterns 212 are formed adjacent to or at the outside of at least part of the periphery of the TSV region 205 on the seed layer 206. The presence of second opening patterns 212 may have the TSV hole 204a once situated in the peripheral of the TSV region 205 adjacent to the isolated portion 207, to be situated in a relatively dense portion, so that all the TSV holes 204 may be situated in an deposition environment with a substantially identical pattern density. In this way, all the TSV holes 204 may be provided with a substantially identical deposition rate, in order to solve the issue of the loading effect.

After the forming of the patterned mask 208, as shown in FIG. 6, a material layer is formed on the exposed seed layer 206, for example, by an electro-chemical plating (ECP) process. In an embodiment of the present invention, the material layer may include, the TSV plugs 214 in the TSV holes 204, the TSV bumps 216 on the TSV holes 204, and the dummy bumps 218 at the outside of at least part of the periphery of the TSV region 205, depending on the coverage of the exposed seed layer 206. The TSV plug 214 and TSV bump 216 construct the TSV structure of present invention. Other masked region covered by mask 208 can't grow any material layer during the electroplating process.

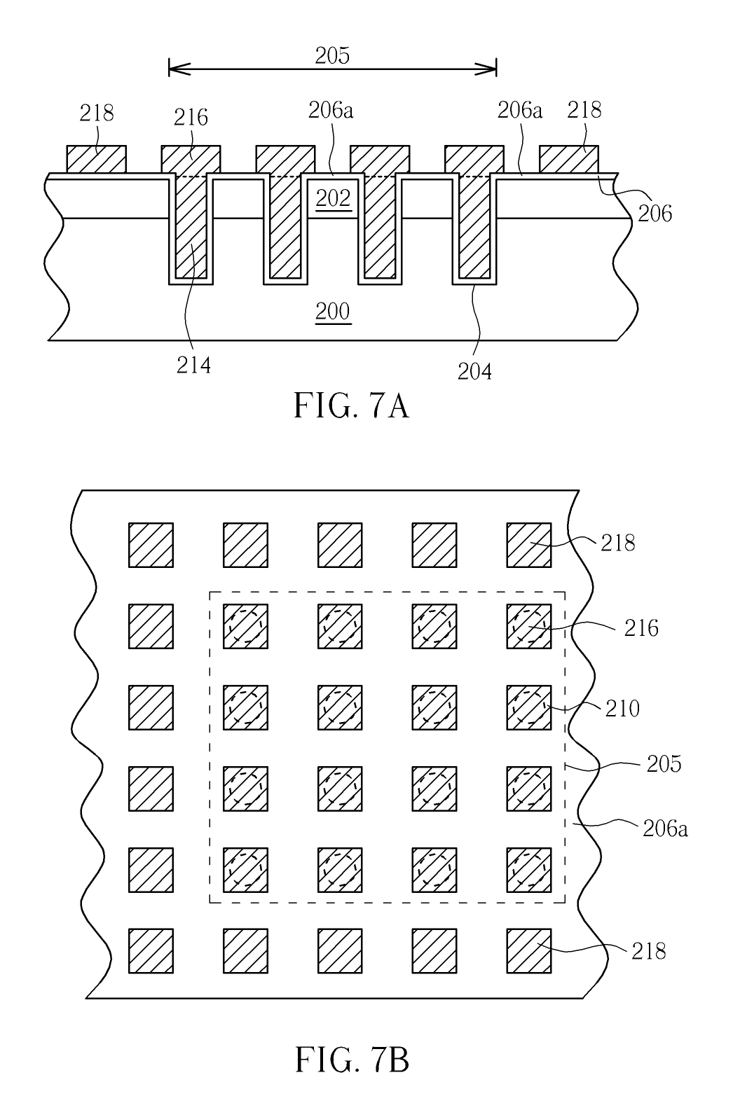

After forming the material layer, as shown in FIGS. 7A and 7B, the mask 208 may be removed to expose the seed layer 206a that was not subjected to the deposition process. The TSV bumps 216 and the dummy bumps 218 may be arranged in a regular array pattern on the surface of the substrate. Please note that, in some embodiment of the present invention, the TSV bumps 216 and the dummy bumps 218 may have shapes that differ from rectangular shapes, such as circular or quasi-circular shapes. Besides, in certain embodiments of present invention, the TSV bumps 216 and dummy bumps 218 may be arranged in an irregular pattern rather than a regular array pattern.

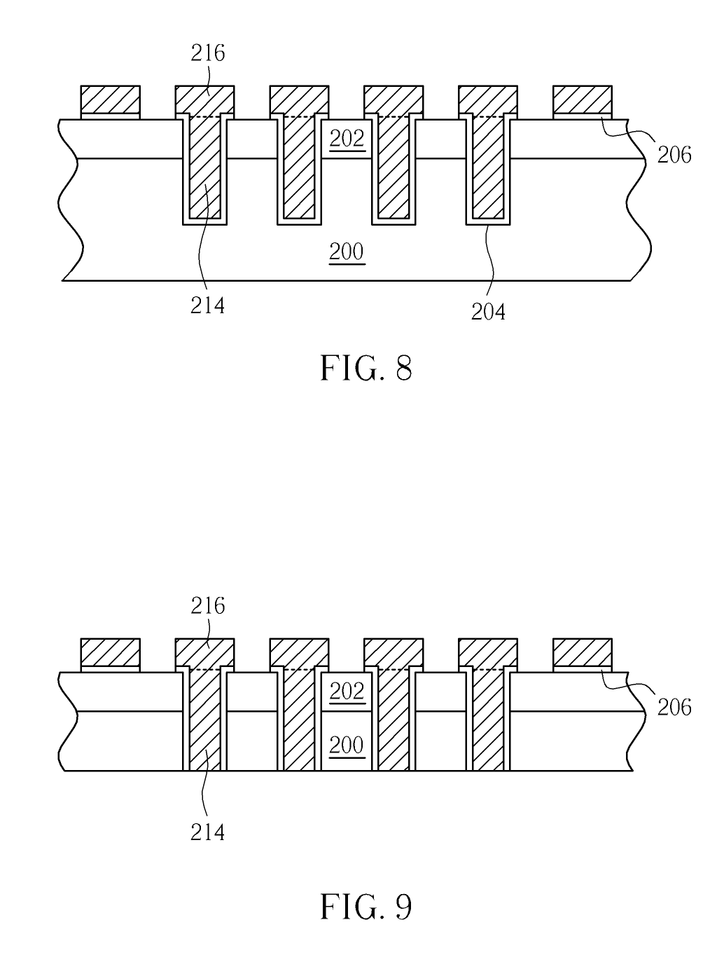

In a last step, as shown in FIG. 8, the exposed seed layer 206a that was not subjected to the deposition process and the barrier layer (not shown) thereunder are removed to electrically isolate the TSV plugs 214 from each other. The TSV electrode structure of the present invention is, therefore, completed. The removing of the seed layer 206a may be achieved through a wet etching process by dipping the entire substrate 200 into an etchant. The selection of etchant may be depended on the materials of seed layer and barrier layer. For example, if the etchant for copper etching is selected in the case, the TSV bumps 216 having the same copper material will also be etched in etching process. Since the seed layer and barrier layer have relatively small thickness, the selective removing of seed layer and barrier may be achieved by controlling the etching time and sacrificing part of the TSV bumps 216.

In a further embodiment of the present invention, as shown in FIG. 9, after the completion of the entire TSV structure, a thinning process may be optionally performed on the substrate 200 to expose the TSV plugs 214 in the substrate 200. The thinning process may be carried out by grinding the back side of the substrate 200 (i.e. the side without deposited dielectric layer 202), by using a chemical mechanical polishing (CMP) process for example, so that the TSV plugs 214 may run through the entire substrate. The exposed TSV plugs 214 may then be used as contacts to electrically connect the TSV structure of other substrate, to construct the 3D-stacked chip structure.

Please note that the aforementioned embodiment utilizes the Via-Middle process. That is, the TSV structure is introduced in the flow between the FEOL process and BEOL process in convention IC manufacturing process. Therefore, a BEOL process may be performed after the manufacture of the entire TSV structure, such as forming metal interconnects or pads structure. TSV structure may be connected to devices or signal sources via the trace formed by the BEOL process.

The present invention may also be applied in other TSV process, such as the Frontside Via-Last process. In this process, the TSV hole is formed by laser or etching after the completion of BEOL process in conventional IC process flow.

Furthermore, the present invention may also be applied in Backside Via-Last process. That is, the wafer will be thinned first from the back side after completing the IC process on the front side, and then an etching process will be performed on the back side of wafer to form require TSV holes.

Besides, the present invention may still be applied in other specific process. For example, in some process, the required TSV hole is formed first from the front side of the wafer by etching method before the formation of any MOS devices. The TSV hole will be filled with oxide and then the FEOL process and BEOL process are performed on the wafer. Subsequently, the wafer is thinned from the back side to expose the oxide in TSV hole which is formed from the front side. The exposed oxide in TSV hole will then be removed to make room for the following TSV forming process.

In other word, no matter the TSV hole is formed from the front side or back side of the substrate, the method of present invention may be appropriately introduced or applied in the process flow thereof. In present invention, the TSV structures and the dummy bumps adjacent to or surrounding said TSV structures are deposited concurrently. The use of dummy bumps may efficiently overcome the issue of conventional loading effect in prior art.

Based on the aforementioned method of manufacturing the TSV, as shown in FIGS. 7A and 7B, the present invention also provides a TSV structure, which comprises a substrate 200, a dielectric layer 202 formed on said substrate 200, a plurality of TSV holes 204 formed in said dielectric layer 202 and said substrate 200 and defining a TSV region 205 on said dielectric layer 202, a seed layer 206 formed on the surface of said dielectric layer 202 and said TSV 204, a plurality of TSV plugs 214, each of said TSV plugs 214 is formed in each of said TSV 204 and formed on said seed layer 206, a plurality of TSV bumps 216, each of said TSV bump 216 is formed on each of said TSV plugs 214, and a plurality of dummy bumps 218 formed at the outside of at least part of the periphery of said TSV region 205 on said seed layer 206.

Please note that in the method and structure of present invention, the flatness of TSV may also be improved by the method other than forming dummy bumps. For example, in still another embodiment of present invention, a plurality of additional dummy TSV holes may be formed adjacent to or surrounding the array of original TSV holes. After the manufacture of TSV structure, the TSV structure in those outmost dummy TSV holes will not be connected with the TSV or I/O contacts of other substrate. Only the TSV structure in original TSV array will be used as the electrical interconnect structure.

Those skilled in the art will readily observe that numerous modifications and alterations of the device and method may be made while retaining the teachings of the invention. Accordingly, the above disclosure should be construed as limited only by the metes and bounds of the appended claims.

1. A through silicon via (TSV) structure, comprising:
a substrate;
a plurality of TSVs embedded in said substrate and protruded from the surface of said substrate; and
a plurality of dummy bumps disposed on the surface of said substrate and adjacent to said plurality of TSVs and electrically isolated from said plurality of TSVs.

2. The through silicon via structure of claim 1, wherein a plurality of seed layers are formed between said plurality of TSVs and said substrate and between said plurality of dummy bumps and said substrate.

3. (canceled)

4. The through silicon via structure of claim 1, further comprising a dielectric layer formed on said substrate, said plurality of TSVs run through said dielectric layer to said substrate.

5. The through silicon via structure of claim 1, wherein said plurality of TSVs and said plurality of dummy bumps are arranged in an array.

6. The through silicon via structure of claim 1, wherein said plurality of TSVs and said plurality of dummy bumps are constituted of copper (Cu) or tungsten (W).

7. A method of manufacturing a through silicon via (TSV), comprising the steps of:
providing a substrate;
forming a plurality of TSVs holes in said substrate from a first surface of said substrate;
forming a seed layer on the surface of said substrate and said plurality of TSVs holes;
forming a patterned mask on said substrate, wherein said patterned mask comprises a plurality of first openings corresponding to said plurality of TSVs holes, and a plurality of second openings adjacent to said plurality of first openings; and
forming a material layer on said substrate, wherein said material layer is filled into said plurality of TSVs holes and said plurality of first openings to form a plurality of TSVs, while said material layer is filled into said plurality of second openings to form a plurality of dummy bumps.

8. The method of claim 7, further comprising the step of removing said patterned mask after forming said plurality of TSVs and said plurality of dummy bumps.

9. The method of claim 7, further comprising the step of removing said seed layer after removing said patterned mask.

10. The method of claim 7, further comprising the step of performing a thinning process from a second surface of said substrate to expose said plurality of TSVs after forming said plurality of TSVs and said plurality of dummy bumps.

11. The method of claim 7, further comprising the step of performing a FEOL (Front-End-of-Line) process and a BEOL (Back-End-of-Line) process on said substrate before forming said plurality of TSV holes.

12. The method of claim 7, further comprising the step of performing a FEOL process on said substrate before forming said plurality of TSV holes.

13. The method of claim 12, further comprising the step of performing a BEOL process on said substrate after forming said plurality of TSVs holes and said plurality of dummy bumps.

14. The method of claim 7, wherein said plurality of TSVs and said plurality of dummy bumps are arranged in array.

15. The method of claim 7, wherein said plurality of TSVs and said plurality of dummy bumps are constituted of copper (Cu) and tungsten (W).

16. The method of claim 6, wherein said plurality of TSVs and said plurality of dummy bumps are formed concurrently by an electro-chemical plating (EPC) process.

17. A through silicon via (TSV) structure, comprising:
a substrate with a TSV region;
a plurality of TSVs embedded in said TSV region of said substrate and protruded from the surface of said substrate; and
a plurality of dummy bumps disposed at the outside of at least part of the periphery of said TSV region on the surface of said substrate, wherein said TSVs in said TSV region are situated in an identical pattern density.

18. The through silicon via structure of claim 1, wherein a plurality of seed layers are formed between said plurality of TSVs and said substrate and between said plurality of dummy bumps and said substrate.

19. The through silicon via structure of claim 1, further comprising a dielectric layer formed on said substrate, said plurality of TSVs run through said dielectric layer to said substrate.

20. The through silicon via structure of claim 1, wherein said plurality of TSVs and said plurality of dummy bumps are arranged in an array.

21. The through silicon via structure of claim 1, wherein said plurality of TSVs and said plurality of dummy bumps are constituted of copper (Cu) or tungsten (W).
